(19) United States
(12) Patent Application Publication
(10) Pub. No.: US 2022/0245309 A1
(43) Pub. Date: Aug. 4, 2022

(54) INFORMATION PROCESSING APPARATUS, INFORMATION PROCESSING METHOD, PROGRAM RECORDING MEDIUM, INFORMATION PROCESSING SYSTEM, INSPECTION DEVICE, AND INSPECTION METHOD

(71) Applicant: CANON KABUSHIKI KAISHA, Tokyo (JP)

(72) Inventor: Yoshiki SAJI, Tochigi (JP)

(21) Appl. No.: 17/590,074

(22) Filed: Feb. 1, 2022

(30) Foreign Application Priority Data
Feb. 4, 2021 (JP) 2021-016339

(51) Int. Cl. G06F 30/27

(52) U.S. Cl. CPC G06F 30/27

(57) ABSTRACT

An information processing apparatus that can estimate, for example, performance of the lens by using a learning model and easily evaluate a quality of the lens. The information processing apparatus comprises: a first acquisition unit configured to acquire first information in which a use state of a lens unit having at least one optical element after shipment is recorded; a second acquisition unit configured to acquire second information in which lens performance or standard of the lens unit or a lens unit different from the lens unit is recorded in advance; and a first processing unit configured to use the first information and the second information as input data of a predetermined learning model, and generate a learned model in which parameters in the learning model are adjusted.

### BACKGROUND OF THE INVENTION

### Field of the Invention

The present invention relates to an information processing apparatus, an information processing method, a program recording medium, an information processing system, an inspection apparatus, and an inspection method.

### Description of the Related Art

In recent years, AI technology including machine learning has been used in various fields, and as a result, analysis of complex events including multiple elements, which has been difficult in the past, has been achieved. Interchangeable lenses (lens devices, lens units) are precision apparatuses in which various elements are combined in a precise and complex manner, and the AI technology is applied also in the field of interchangeable lenses to try to solve various problems.

In contrast, the interchangeable lenses require periodic maintenance, and it is generally left to the user to determine whether or not maintenance is necessary. However, as described above, since the interchangeable lenses are a complicated and precise apparatuses, it is difficult to determine whether or not maintenance is necessary. In order to support the determination of whether or not maintenance is necessary, the method for estimating and evaluating the performance of an interchangeable lens, and informing a user of the lens quality of the interchangeable lens is disclosed.

In Japanese Patent Application Laid-Open No. 2017-156643, performance estimation is performed by comparing the durability information of each driving unit of the interchangeable lens with the operation records of the interchangeable lens. The durability information is set for each model of the interchangeable lens, and is uniformly applied to all interchangeable lenses of the same model. However, the degree of performance change of the interchangeable lens is different depending on the use environment, including temperature and humidity, and the result of quality evaluation for the interchangeable lens by using the method in Japanese Patent Application Laid-Open No. 2017-156643 may be different from the actual lens quality.

### SUMMARY OF THE INVENTION

The present invention provides an information processing apparatus capable of estimating, for example, the performance of a lens by using a learning model, and easily evaluate the quality of the lens.

An information processing apparatus as an aspect of the present invention, comprising: a first acquisition unit configured to acquire first information in which a use state of a lens unit having at least one optical element after shipment is recorded; a second acquisition unit configured to acquire second information in which lens performance or standard of the lens unit or a lens unit different from the lens unit is recorded in advance; and a first processing unit configured to use the first information and the second information as input data of a predetermined learning model, and generate a learned model in which parameters in the learning model are adjusted.

Further features of the present invention will become apparent from the following description of exemplary embodiments with reference to the attached drawings.

### BRIEF DESCRIPTION OF THE DRAWINGS

FIG. 1 illustrates an example of an information processing system configuration diagram in the first embodiment.

FIG. 2A and FIG. 2B illustrate an example of a hardware configuration of a learning phase in the first embodiment.

FIG. 3 illustrates an example of a hardware configuration of an estimation phase in the first embodiment.

FIG. 4 is a flowchart illustrating a process for lens quality evaluation in which the learning phase and the estimation phase are performed in the first embodiment.

FIG. 5 is a flowchart illustrating a process for measuring a lens condition when the lens is brought into a maintenance base in the first embodiment.

FIG. 6 is a flowchart illustrating the learning processing for a lens performance estimation model in the first embodiment.

FIG. 7 is a flowchart illustrating a process of lens performance estimation and quality evaluation in the first embodiment.

FIG. 8 illustrates an example of an information processing system configuration diagram in the second embodiment.

FIG. 9 is a flowchart illustrating a process of lens quality evaluation including shipment lens performance measurement in the second embodiment.

FIG. 10 is a flowchart illustrating a process of the shipment lens performance measurement in the second embodiment.

FIG. 11 is a flowchart illustrating a measurement flow of a lens condition when the lens is brought into the maintenance base in the second embodiment.

FIG. 12 is a flowchart illustrating the learning processing for the lens performance estimation model in the second embodiment.

FIG. 13 is a flowchart illustrating the lens performance estimation and quality evaluation processing in the second embodiment.

### DESCRIPTION OF THE EMBODIMENTS

A preferred embodiment of the present invention will be described below with reference to the accompanying drawings. In each of the drawings, the same members or elements are denoted by the same reference numerals and redundant description will be omitted or simplified.

### First Embodiment

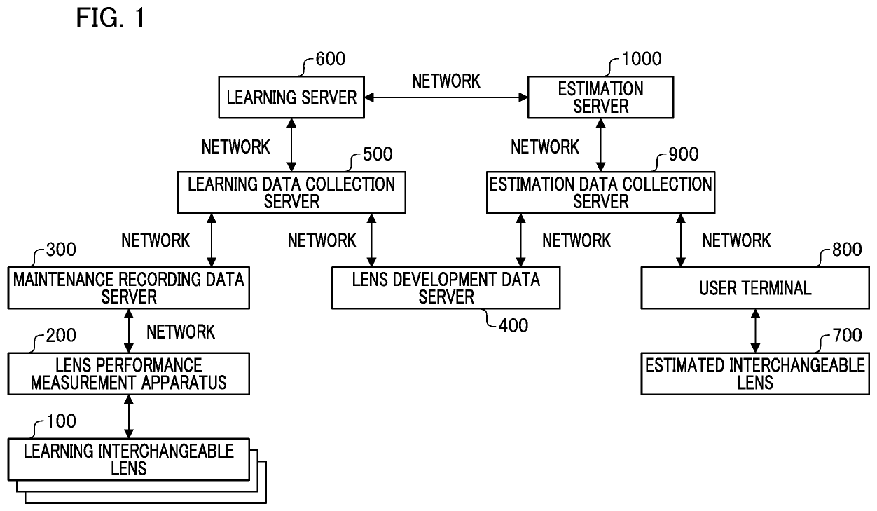

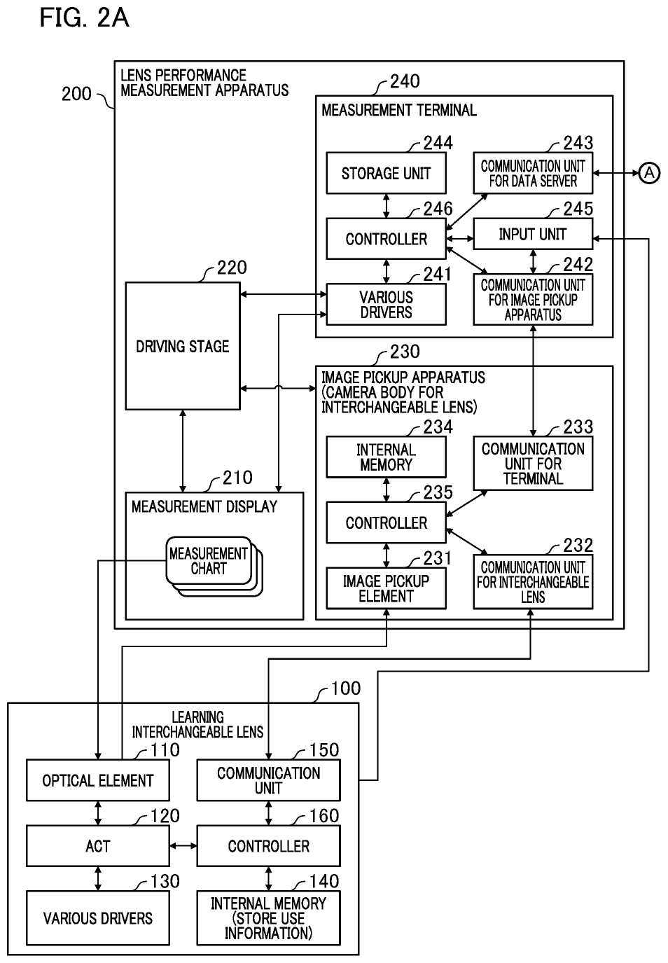

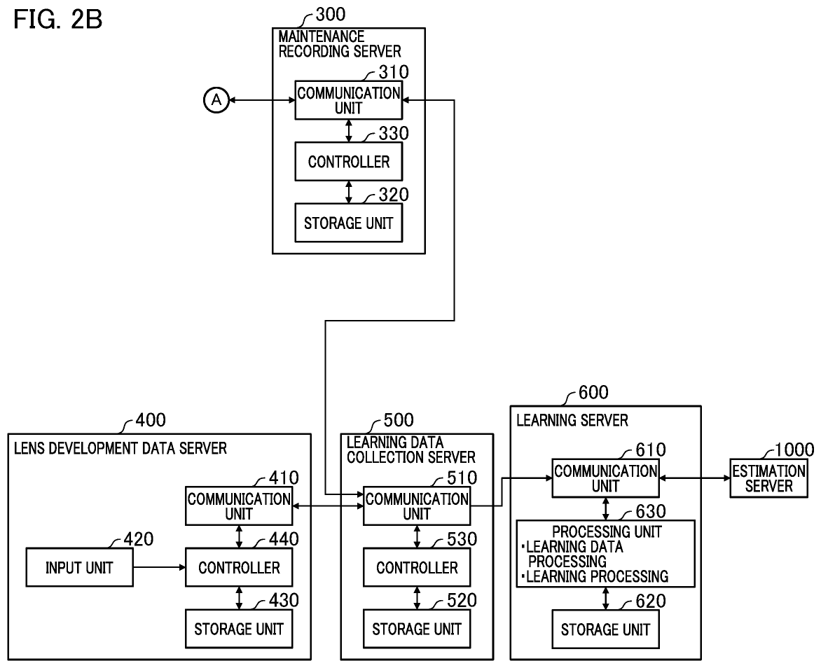

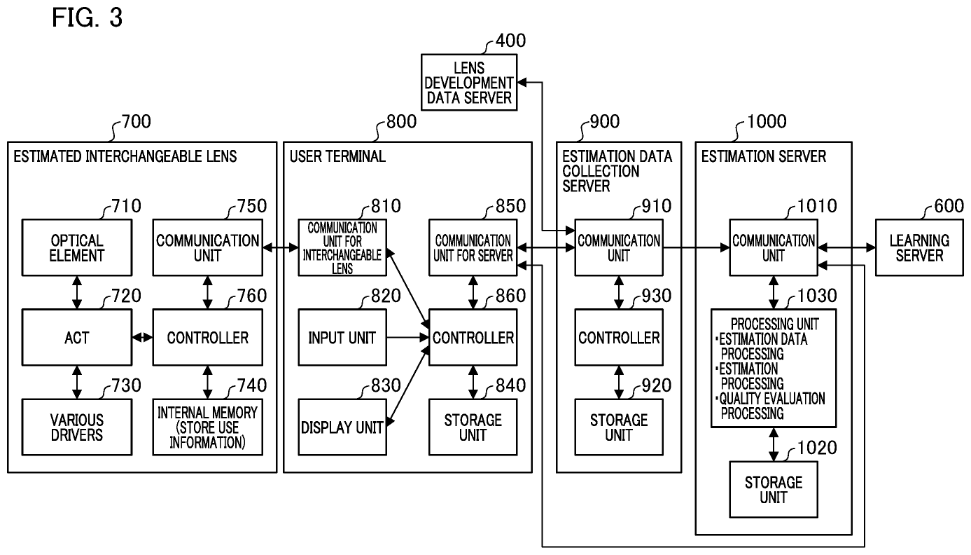

FIG. 1 is an example of a configuration diagram of an information processing system (quality evaluation system) in the first embodiment. The information processing system in the first embodiment includes an learning interchangeable lens (hereinafter, referred to as an “interchangeable lens”) 100, which is a lens unit, and a lens performance measurement apparatus (hereinafter, referred to as a “measurement apparatus”) 200. The information processing system further includes a maintenance recording server (hereinafter, referred to as a “server apparatus”) 300, a lens development data server (hereinafter, referred to as a “server apparatus”) 400, and a learning data collection server (hereinafter, referred to as a “server apparatus”) 500. The information processing system further includes a learning server 600, an estimated interchangeable lens (hereinafter, referred to as an “interchangeable lens”) 700, a user terminal 800, an estimation data collection server (hereinafter, referred to as a “server apparatus”) 900, and an estimation server 1000. Each of the above configurations in the information processing system according to the first embodiment will be described below with reference to FIG. 2 and FIG. 3.

Next, a system configuration of a learning phase in the information processing system according to the first embodiment will be described with reference to FIG. 2. FIG. 2 illustrates an example of a hardware configuration in the learning phase of the first embodiment. FIG. 2A illustrates an example of a hardware configuration of the interchangeable lens 100 and the measurement apparatus 200 in the learning phase. FIG. 2B illustrates an example of a hardware configuration of the server apparatus 300, the server apparatus 400, the server apparatus 500, and the learning server 600. As shown in FIG. 2, the hardware configuration of the information processing system in the learning phase according to the first embodiment includes the interchangeable lens 100, the measurement apparatus 200, the server apparatus 300, the server apparatus 400, the server apparatus 500, and the learning server 600.

The interchangeable lens (learning interchangeable lens) 100 is an interchangeable lens to which the measurement of the lens performance of is performed in facilities where various measuring facilities are equipped with such as a maintenance base and a production factory in various locations, in response to a request for maintenance or the like from a user who uses the interchangeable lens. In the first embodiment, the interchanging lens 100 serving as a lens for an interchangeable camera will be described. The interchangeable lens 100 includes an optical element 110, one or more actuators (ACT) 120, various drivers 130, an internal memory 140, a communication unit 150, and a controller 160.

The optical element 110 configures an image forming optical system including a lens group, a diaphragm, a focus mechanism, and an image stabilization mechanism. The optical element 110 has a function for forming an image of various measurement charts displayed on a measurement display (hereinafter, referred to as a “display”) 210 during measurement of lens performance, which will be described below, on an image pickup element 231.

The actuator 120 is used for driving the optical element 110, and a plurality of actuators 120 may be provided in the interchangeable lens 100. The examples of the actuator 120 include a group driving unit for moving a focus lens group and a zoom lens group in the optical axis direction, an image stabilization driving unit for moving an image stabilization mechanism, a driving unit for moving a diaphragm, and a ND filter.

The various drivers 130 function as drivers that transmit electric signals for driving the actuator 120 to the actuator 120. The internal memory 140 stores first information indicating the use state of the interchangeable lens 100, which will be described below, as needed, in addition to information about various types of control of the interchangeable lens 100. The communication unit 150 transmits and receives a variety of information to and from an image pickup apparatus 230, which will be described below, based on instructions from the controller 160.

The controller 160 includes a CPU (Central Processing Unit), and is connected to each unit of the interchangeable lens 100 via a line. The controller 160 can integrally control, for example, the operation of the interchangeable lens 100 according to a program stored in the internal memory 140 and the like of the interchangeable lens 100. The controller 160 has a function for transmitting various control signals (control instructions) to the measurement apparatus 200 and the like.

Although, in the first embodiment, the interchangeable lens 100 is described to serve as an interchangeable camera lens, it may be a lens device integrated with an image pickup element, an optical element member, for example, an extender or various filters, that does not function as a single body. The interchangeable lens 100 may be an optical apparatus, for example, a telescope, binoculars, a range finder, and a surveying instrument. The same also applies to the interchangeable lens 700 to be described below. If the measurement of lens performance for the interchangeable lens 700 has been performed in response to a maintenance request or the like in the past, the interchangeable lens 700 at that time may be treated as the interchangeable lens 100 described above.

The measurement apparatus (lens performance measurement apparatus) 200 is a measurement apparatus capable of acquiring first information indicating a lens use condition of, for example, the interchangeable lens 100 to be described below, and fourth information indicating the lens performance. The measurement apparatus 200 is configured by the display 210, a driving stage 220, the image pickup apparatus 230, and a measurement terminal 240.

The display (measurement display) 210 displays the various measurement charts on a display (on a screen) based on signals from various drivers 241 in the measurement terminal 240 to be described below.

The driving stage 220 performs translational driving of the display 210 and the image pickup apparatus 230 in the optical axis direction and the optical axis orthogonal direction, and rotational driving around each axis, based on signals from the various drivers 241 in the measurement terminal 240 as necessary. Thus, it is possible to measure items related to image stabilization performance by driving a stage to which the image pickup apparatus is attached, and it is possible to measure items related to tracking performance of an object by driving a stage to which a measurement display is attached.

The image pickup apparatus 230 is a camera body capable of exchanging lenses and includes the image pickup element 231, a communication unit for interchangeable lens (hereinafter, referred to as a “communication unit”) 232, a communication unit for a terminal (hereinafter, referred to as a “communication unit”) 233, an internal memory 234, and a controller 235.

The image pickup element 231 acquires a video displayed on a display for measurement through the interchangeable lens 100. The communication unit (communication unit for interchangeable lens) 232 transmits and receives a variety of information to and from the interchangeable lens 100 based on an instruction from the controller 235. The communication unit (communication unit for terminal) 233 transmits and receives a variety of information to and from the measurement terminal 240 based on an instruction from the controller 235. The internal memory 234 stores a variety information transmitted from the interchangeable lens 100.

The controller 235 includes a CPU and is connected to each unit of the image pickup apparatus 230 via a line. The controller 235 has a function for transmitting various control signals to the image pickup apparatus 230 and the interchangeable lens 100 according to a program stored in the internal memory 234 based on an instruction from the measurement terminal 240.

In the first embodiment, although the image pickup apparatus 230 serves as a camera body capable of exchanging lenses as described above, it may be a dedicated measuring apparatus. The information about images and video images acquired by the image pickup apparatus 230 is stored in the internal memory 234, and is transmitted to the measurement terminal 240 via the communication unit 233 by the controller 235.

The measurement terminal 240 includes a communication unit for an image pickup apparatus (hereinafter, referred to as a “communication unit”) 242, a communication unit for a data server (hereinafter, referred to as a “communication unit”) 243, a storage unit 244, an input unit 245, a controller 246, and the various drivers 241.

The communication unit 242 (communication unit for the image pickup apparatus) transmits and receives a variety of information to and from the image pickup apparatus 230 based on an instruction from the controller 246. The communication unit (communication unit for data server) 243 transmits and receives a variety of information to and from the server apparatus 300 based on an instruction from the controller 246. The storage unit (memory) 244 saves (stores) various data. The input unit 245 can input various measurement items and measurement conditions, and the degree of wear of components including the interchangeable lens 100. The controller 246 includes a CPU and is connected to each unit of the measurement terminal 240 via a line. The controller 246 transmits various control instructions to each unit of the measurement terminal 240 based on the input from the input unit 245 according to the program stored in the storage unit 244. The various drivers 241 transmit an electric signal for driving each driving unit of the measurement apparatus 200.

A server apparatus (maintenance recording data server) 300 is a database for storing (saving) and managing first information and fourth information acquired by the measurement apparatus 200 for each interchangeable lens 100. The server apparatus 300 includes a communication unit 310 communicable with the measurement apparatus 200 and the server apparatus 500, a storage unit 320 for storing various data, and a controller 330 for controlling the entire server apparatus 300.

The server apparatus (lens development data server) 400 is a database for storing and managing various data in advance that are acquired when lens is developed including second information indicating lens durability performance, standards, and the like, for each model. Various data acquired when lens is developed including the above second information are information about the interchangeable lens, which is different from the interchangeable lens 100 or the interchangeable lens 100 to be described below. The server apparatus 400 includes a communication unit 410 communicable with the server apparatus 500, an input unit 420 capable of inputting a variety of information, a storage unit 430 that stores various types of data, and a controller 440 that controls the entire server apparatus 400. The second information about the lens endurance performance is stored in the storage unit 430 of the server apparatus 400 by the controller 440 by inputting a variety of information from the input unit. Additionally, the controller 440 may acquire the second information stored in, for example, an external server apparatus (for example, storage unit) and store it in the storage unit 430 without input from the input unit 420. In this case, the server apparatus 400 and the server apparatus 300 may be the same server apparatus (server equipment).

The server apparatus (learning data collection server) 500 collects various learning data used for machine learning to be described below. The server apparatus 500 is, for example, an information processing apparatus configured by at least one computer in which a program is incorporated. The server apparatus 500 includes a communication unit 510, which will be described below, communicable with the server apparatus 300, the server apparatus 400, and the learning server 600, a storage unit 520 that stores various data, and a controller 530 that controls the entire server apparatus 500. In this case, the server apparatus 500, the server apparatus 300, and the server apparatus 400 may be the same server apparatus.

The learning server 600 performs machine learning for obtaining a lens performance estimation function to be described below. The learning server 600 is, for example, an information processing apparatus configured by at least one computer in which a program is incorporated. The learning server 600 includes a communication unit 610 communicable with the server apparatus 500 and the estimation server 1000, a storage unit 620 that stores various data, and a processing unit (controller) 630 that performs a process for data for learning and learning processing. The processing unit 630 includes a CPU and is connected to each unit of the learning server 600 via a line. The processing unit 630 can integrally control, for example, the operation of the learning server 600 according to a program stored in the storage unit 620 and the like of the learning server 600. The processing unit 630 also has a function for transmitting various control signals (control instructions) to the server apparatus 500, the estimation server 1000, and the like.

In the processing unit 630, machine learning for updating parameters in a model is executed a plurality of times by using a learning model. If, in the processing unit 630, learning is performed a plurality of times by using a learning model including machine learning, it is effective to use a GPU (Graphics Processing Unit) by which parallel processing of data can be efficiently calculated. In the first embodiment, the GPU is used in addition to the CPU for the processing performed by the processing unit 630. When a learning program that includes the learning model is executed, learning is performed by the CPU and the GPU cooperating with each other to perform calculations. In the processing by the processing unit 630, either the CPU or the GPU is used to perform calculation. In this case, the learning server 600 and the server apparatus 500 may be the same server apparatus.

Next, a system configuration in the estimation phase in the first embodiment will be described with reference to FIG. 3. FIG. 3 illustrates an example of a hardware configuration in the estimation phase of the first embodiment. The hardware configuration in the estimation phase in the first embodiment includes the interchangeable lens 700, the user terminal 800, the server apparatus 900, and the estimation server 1000.

The interchangeable lens (estimated interchangeable lens) 700 is an interchangeable lens serving as an object to be evaluated in the first embodiment. The interchangeable lens 700 will be described as an interchangeable camera lens in the first embodiment. The interchangeable lens 700 includes an optical element 710, an actuator (ACT) 720, various drivers 730, an internal memory 740, a communication unit 750, and a controller 760.

The optical element 710 configures an imaging optical system including a lens group, a diaphragm, a focus mechanism, and an image stabilization mechanism. The actuator 720 is an actuator for driving the optical element 710, and a plurality of actuators 720 may be provided in the interchangeable lens 700. The examples of the actuator 720 include a group driving unit for moving a focus lens group and a zoom lens group in the optical axis direction, an image stabilization driving unit for moving the image stabilization mechanism, and a driving unit for moving the diaphragm and the ND filter.

The various drivers 730 function as drivers that transmit electric signals for driving actuator 720 to actuator 720. The internal memory 740 stores, for example, first information indicating the use state of the interchangeable lens 700 to be described below as needed, in addition to information about various types of control of the interchangeable lens 100. The communication unit 750 transmits and receives a variety of information to and from the user terminal 800, which will be described below, based on an instruction from the controller 760.

The communication unit 750 may be a communication unit, for example, a USB terminal provided exclusively for the interchangeable lens 700, or may be in the form in which the interchangeable lens 700 is mounted on the camera main body (image pickup apparatus) and various communication units provided on the camera main body are used. The communication method may be a wired method via various cables or a wireless method using Wi-Fi (Wireless Fidelity) (registered trademark), Bluetooth (registered trademark), or the like.

The controller 760 includes a CPU and is connected to each unit of the interchangeable lens 700 via a line. The controller 760 integrally controls the operation and adjustment of the interchangeable lens 700 in accordance with a program stored in, for example, the internal memory 740 of the interchangeable lens 700. The controller 760 has a function for transmitting various control signals (control instructions) to the user terminal 800 and the like.

In the first embodiment, as in the interchangeable lens 100, the interchangeable lens 700 is described as an interchangeable lens for a camera. However, the interchangeable lens 700 may be a lens device integrated with an image pickup element, or an optical element member that does not function by itself, for example, an extender and various filters. Additionally, the interchangeable lens 700 may be optical devices such as a telescope, a binocular, a range finder, and a surveying instrument.

The user terminal 800 is an apparatus that acquires first information and the like stored in the internal memory 740 of the interchangeable lens 700. The user terminal 800 includes a communication unit for an interchangeable lens (hereinafter, a communication unit) 810 communicable with the interchangeable lens 700, an input unit 820 into which a user can input a variety of information, and a display unit 830 on which a variety of input information, lens quality evaluation results, and the like are displayed. The user terminal 800 includes a storage unit 840 that stores various data, a communication unit for server (hereinafter, referred to as a “communication unit”) 850 communicable with the server apparatus 900 and the estimation server 1000, and a controller 860 that controls the entire user terminal 800. The examples of the user terminal 800 include an information processing apparatus (information processing terminal), for example, a personal computer and a smartphone, and a lens interchangeable camera body.

The server apparatus (estimation data collection server) 900 collects various estimation data used for the lens performance estimation of the interchangeable lens 700 and the like. The server apparatus 900 is, for example, an information processing apparatus configured by at least one computer in which a program is incorporated. The server apparatus 900 includes a communication unit 910 communicable with the user terminal 800 and the server apparatus 400, a storage unit 920 that stores various data, and a controller 930 that controls the entire server apparatus 900. The controller 930 includes a CPU, and is connected to each unit of the server apparatus 900 via a line. The controller 930 can integrally control, for example, the operation of the server apparatus 900 according to a program stored in, for example, the storage unit 920 of the server apparatus 900. The controller 930 also has a function for transmitting various control signals (control instructions) to the server apparatus 400, the user terminal 800, the estimation server 1000, and the like. Additionally, the server apparatus 900 and the server apparatus 400 may be the same server apparatus.

The estimation server 1000 executes lens performance estimation and evaluates lens quality. The estimation server 1000 is, for example, an information processing apparatus configured by least one computer in which a program is incorporated. The estimation server 1000 includes a communication unit 1010 communicable with the server apparatus 900 and the learning server 600, a storage unit 1020 that stores various data, and a processing unit (controller) 1030 that performs the processing of data for estimation and quality evaluation processing. The processing unit 1030 includes a CPU and is connected to each unit of the learning server 600 via a line. The processing unit 1030 can integrally control, for example, the operation of the estimation server 1000 according to a program stored in, for example, the storage unit 1020 of the estimation server 1000. The processing unit 1030 also has a function for transmitting various control signals (control instructions) to the learning server 600, the server apparatus 900, and the like.

In the processing unit 1030, a GPU is used in addition to the CPU as in the processing unit 630 of the learning server 600 described above, and calculation may be performed by either the CPU or the GPU. The estimation server 1000, the learning server 600, and the server apparatus 900 may be the same server apparatus.

Next, the first information indicating the use record of the interchangeable lenses such as the interchangeable lens 100 and the interchangeable lens 700 after shipment will be described below. First, the examples of the first information include drive recording of the interchangeable lens 100 and the interchangeable lens 700. The examples of the drive recording include the driving frequency of the driving unit of the interchangeable lens 100 and the interchangeable lens 700. The examples of the driving unit include a diaphragm, a focus mechanism, a zoom mechanism, and an image stabilization mechanism. Instead of the simple addition of the number of times of operation, a unique criterion for calculating the number of times, for example, setting three times as one step, may be provided.

Additionally, there are cases in which the appearance degree of the wear and the like of the member caused by driving is different depending on the driving time, the driving speed, and the like. Accordingly, the first information may indicate information based on the driving time, the driving distance, and the driving speed (driving information). Additionally, the driving characteristics (control information) of actuators such as the actuator 120 and the actuator 720 that drive each unit of the interchangeable lens 100 and the interchangeable lens 700, which is used as the control record, may be indicated by the first information. The examples of the driving characteristics include a starting voltage, a starting frequency, a maximum speed, a step-out speed, and a driving voltage depending on each actuator, and the controllability of the interchangeable lens 100 and the interchangeable lens 700 can be evaluated by acquiring the information.

Typically, the interchangeable lenses cause changes in performance depending on the environment in which the lenses are used. The examples of change in performance include the deterioration of parts and lens mold in response to temperature and humidity, rattling of lens barrel assembly and parts breakage of the interchangeable lenses in response to acceleration and impact, and contamination of foreign matter by dust and sea breeze. The information about the environment where the interchangeable lens 100 and the interchangeable lens 700 are used may be recorded as the first information. It is assumed that the examples of the information include various kinds of recording information including temperature recording (temperature information), humidity recording (humidity information) inside and outside the interchangeable lens, external force recording by acceleration, angular acceleration, and impact degree (information of external force), and climate recording by position information. In this case, the interchangeable lens 100 or the interchangeable lens 700 may be provided with sensors such as a temperature sensor and a GPS. Further, a dedicated battery or the like may be provided so that various data can be recorded even when the interchangeable lens 100 or the interchangeable lens 700 is not connected to the camera body.

In the first information described above, the use history of the interchangeable lens 100 and the interchangeable lens 700 can be specified in detail by increasing the number of items of the first information, and, in machine learning to be described below, the accuracy of the estimation lens performance can be improved. Therefore, it is preferable that all the variety of information described above are used as items of the first information. Additionally, the items may be created by combining the variety of information described above depending on the situation. Although the first information in the interchangeable lens 100 and the interchangeable lens 700 has been described above, the same is applied to other lens devices other than the interchangeable lens 100 and the interchangeable lens 700.

Next, the second information about the quality test acquired before shipment of the interchangeable lens and acquired in the development process will be described below. The second information is acquired by an interchangeable lens (reference lens for test) or the like, which is another part that is different from the interchangeable lens 100 and the interchangeable lens 700. The reference lens for testing is used to acquire measurement data in factories and the like and is basically not forwarded.

In the development process, a quality test assuming various methods and environments in which the interchangeable lenses are used is performed. In the first embodiment, the test conditions at that time and the lens performance and standard after the test are used as the second information in the interchangeable lens 100 and the interchangeable lens 700. Thus, it is possible to learn about how much each factor that causes performance changes, such as drive frequency and temperature, affects each performance change in the machine learning described below. The examples of the test contents in the second information include environmental tests assuming various climates (environmental test information), endurance tests of various driving units (endurance test information), static pressure tests (load test information), vibration tests (vibration test information), and impact tests (impact test information). The test conditions include temperature, humidity, time, drive frequency, load, and vibration frequency according to the test contents.

The examples of the item for evaluation as a lens performance after the test include optical performance based on MTF % to be described below (optical performance information), lens barrel operation performance including drive characteristics of each actuator (operation performance information), and dustproof or drip-proof performance (dust-proof and drip-proof performance information). Additionally, the examples of the item include evaluation of the degree of wear of the components (information about the degree of wear), and sensory evaluation for the appearance, operation state (operational feeling) (evaluation information). Here, the data indicating the lens performance of the interchangeable lens after testing may be a quantitative numerical value indicating each performance or a classification indicating OK/NG of the standard.

The examples of the fifth information about the product specification include size and mass of product catalogue data, lens configuration, focal length, aperture value, product design information including a drive system, component material, various dimensions, and manufacturing information including design time information and manufacturing time information at a manufacturing plant. The fifth information may be added to the second information. Thus, in the machine learning to be described below, it is possible to learn the similarity of specifications between the product models of the interchangeable lenses, to find a shared trend according to the product specifications, and to improve the accuracy of the estimation lens performance.

The examples of the shared trend described above include a manner in which an external force is applied, a manner in which optical performance is changed, a manner in which driving characteristics are changed, and a manner in which various components are worn or consumed. Accordingly, it is possible to estimate the performance even for a new product with few maintenance records based on the information about the products in the past, which are similar to the new product. Although it has been described that the second information is acquired by an interchangeable lens, which is another part that is different from the interchangeable lens 100 and the interchangeable lens 700, the present invention is not limited thereto, and the second information may be acquired from the interchangeable lens 100 and the interchangeable lens 700.

Next, the fourth information indicating the lens performance based on the result of the actual operation of the interchangeable lens 100 by the user will be described below.

TABLE 1

| Sub-variable information | | | Z direction | 1 | 2 | 3 | . . . | 64 |
|---|---|---|---|---|---|---|---|---|
| Optical axis | X = 0 | Y direction | | | | | | |
| direction position | | | | | | | | |
| Wavelength (color) | Co = white | 1 | | 64 | 65 | 65 | . . . | 58 |
| Spatial frequency | f = 10 | 2 | | 65 | 66 | 67 | . . . | 59 |
| Focal length | Z = 24 | 3 | | 64 | 66 | 68 | . . . | 60 |
| Object distance | Fo = ∞ | . . . | | . . . | . . . | . . . | . . . | |
| Aperture value | Iris = 2.8 | . . . | | . . . | . . . | . . . | . . . | |
| information | | | | | | | | |
| Orientation | g = positive position | . . . | | . . . | . . . | . . . | . . . | |
| Direction | Di = sagittal | . . . | | 70 | 71 | 72 | . . . | 65 |
| Presence or | Ad = none | | | 70 | 72 | 72 | . . . | 64 |
| absence of adapter | | | | | | | | |

The fourth information is collected at facilities with a variety of measurement equipment, such as various maintenance bases and production plants. The fourth information is, for example, Table 1, which is table data (hereinafter, referred to as “MTF % data”) storing percentages of MTF (modulation transfer functions) at each image plane position, which is one of indexes indicating the optical performance of the lens. The table data are expressed by “Mathematical 1” below.

Table [001]{y,z}(x,Co,f,Z,Fo,Iris,g,Di,Ad) (Mathematical 1)

“Table” in Mathematical 1 indicates table data, and the number in square brackets [ ] indicates serial number of the table data. The MTF % data is set to 001. The characters in curly brackets { } are the main variables of the table data, and indicate that the size of the two-dimensional table is an array of y rows×z columns. For convenience, in this context, the number of data is one sheet. Characters in parentheses ( ) indicate sub-variables, and indicate that table data for the number of combinations of sub-variables exist.

Next, each variable in the above “Mathematical 1” will be described in detail. With reference to the position where the interchangeable lens 100 is attached to the measurement apparatus 200, “y” and “z” are divided equally into 64 parts, where “y” is a vertical position and “z” is a horizontal position.

“x” indicates a position in the optical axis direction (mm), and when the position of the imaging plane is 0 (zero), the image plane side is +(plus) and the opposite side is − (minus). The movement may be realized by moving the imaging plane, moving the object distance, moving the focus lens group, or the like. “Co” indicates a color of a light source (wavelength) used during measurement, and a specific spectral waveform is used with white light in the first embodiment.

“f” indicates a spatial frequency (number/mm). “Z” indicates a focal length (mm). “Fo” indicates an object distance (m). “Iris” indicates an aperture value. “g” indicates a direction of gravity. “Di” indicates a direction of the black and white chart line during MTF measurement. “g” is typically distinguished in the words of sagittal and meridional directions, or vertical and horizontal lines. “Ad” indicates the presence or absence of an adapter represented by an extender. The present data format is not limited thereto, and, for example, R and 0 coordinate systems may be used instead of y and z, and Fo may be substituted by a moving amount of a focus lens, instead of the object distance.

Next, an example of data used when the measured MTF % data table is used as the fourth information indicating the lens performance will be described. As in Table [001], the MTF % data of the design values in the same model are represented by “Mathematical 2” below to serve as Table [001′].

Table [001′]{y,z}(x,Co,f,Z,Fo,Iris,g,Di,Ad) (Mathematical 2)

Here, formula (1) below is used to calculate the performance change rate during MTF % measurement. Each calculation in the formula (1) below and the formula below is performed by calculating the numbers in each array data of the same variables.

Table [001]{y,z}(x,Co,f,Z,Fo,Iris,g,Di,Ad)/Table [001′]{y,z}(x,Co,f,Z,Fo,Iris,g,Di,Ad)×100=AAA (1)

Formula (1) indicates the degree of deterioration from the design value during measurement under each variable condition by using a percentage, and the result of the above formula (1) is denoted by “AAA” for ease of description. Moreover, Table [001′] is stored on each data server to serve as a representative value for each product model.

Next, the table data for weighting the MTF % data is expressed by Table [002] in “Mathematical 3” below.

Table [002]{y,z}(x,Co,f,Z,Fo,Iris,g,Di,Ad) (Mathematical 3)

In Table [002] in “Mathematical 1”, for example, when variables x=−1, 0, +1 are set, x=0, in which other variables are in focus under specific conditions is set to weight 1. “x=−1”, in which the front side with respect to the focusing position is shot is set to weight 0.5, and “x=+1”, in which the back side with respect to the focusing position is shot is set to weight 0.3. “x=−1” becomes a parameter for evaluating referred to as “blurring” by combining variable Iris, and under the condition of large focal length Z with a shallow depth, the weight at x=−1 is increased to 0.6. When the object distance Fo is an Go distance, usually no object farther than infinity exists, and thus, the weight of x=−1 is set to 0 and the weight of x=+1 is set to 0.7. However, the present invention is not limited thereto, and various weighting methods exist depending on the variable, and thus, a weighting method different from the above may be used depending on the situation.

In the first embodiment, Table [002], which is data for weighting, is stored on each data server to serve as a representative value for each product model. However, a modified example in which different data are used or the amount of weighting is changed based on information from the input unit of various terminals may be used. Here, the following formula (2) is calculated to perform weighting on each variable.

Table [002]{y,z}(x,Co,f,Z,Fo,Iris,g,Di,Ad)×AAA=BBB (2)

The result of the above formula (2) is denoted by “BBB” for ease of description. The average value of the data stored in the BBB table data can be reworded as a weighted average value obtained by weighting each variable, and the average value is used as the fourth information in the first embodiment to serve as the lens performance based on the MTF % data.

Although the fourth information based on the MTF % data has been described above, the fourth information may be the MTF % table data itself under each variation condition or image data obtained by shooting the measurement chart. Items related to the lens performance are not limited to MTF % data and various data can be assumed. The examples of the items include an amount of deviation of the peripheral light amount from the optical axis and an amount of deviation of distortion from the optical axis, an amount of chromatic aberration of magnification, an amount of image plane curvature calculated based on the MTF % data and an amount of astigmatism of the lens, and the surface accuracy of spherical and aspherical lenses.

Further, in addition to the optical performance based on the MTF %, the information about the lens barrel operation performance including the drive characteristics of each actuator, the dust-proof or drip-proof performance, and the sensory evaluation for the appearance and the operating state may be added to the lens evaluation items in the fourth information. Additionally, for example, the degree of wear of each lens barrel member configuring the interchangeable lens 100 (wear degree evaluation) may be added to the lens evaluation items in the fourth information. The items of the wear degree evaluation include items that can be confirmed by lens inspection or overhauling, such as appearance, internal view, degree of wear of cam groove and cam pin, an amount of grease in each sliding part, rattling of lens barrel assembly, and the peeling of member. Consequently, it is possible to evaluate not only the optical performance but also the visual quality, the operation accuracy of the lens barrel, the dust-proof/drip-proof performance, the operation feeling, and the like.

By increasing the items of the fourth information by the various measurements described above, it is possible to increase the items of the third information, which is the estimated lens performance output by a machine learning model to be described below.

Next, the machine learning executed by the learning server 600, the lens performance estimation process, and the lens quality evaluation in the estimation server 1000 will be described below.

In the learning server 600, machine learning using the first information and the second information as input data and fourth information as teacher data are performed. In the first embodiment, an algorithm used for the machine learning model is described in detail as deep learning that generates a feature quantity and a coupling weighting coefficient for learning by itself by using a neural network. The present invention is not limited thereto, and machine learning algorithms such as nearest neighbor algorithms, naive Bayes method, decision tree, and a support vector machine may be used for application to the first embodiment.

The learning model includes an error detection unit and an update unit. The error detection unit acquires an error between output data that is output from an output layer of the neural network according to input data that is input to an input layer, and teacher data. The error detection unit may calculate an error between the output data from the neural network and the teacher data by using the loss function.

The update unit further updates, for example, a coupling weighting coefficient between nodes of the neural network so that the error is reduced based on the error obtained by the error detection unit. The update unit updates the coupling weighting coefficient or the like by using, for example, the error back propagation method. The error back propagation method is a method for adjusting, for example, a coupling weighting coefficient between nodes of each neural network so that the error is reduced.

By the above machine learning, the neural network can estimate lens performance for an individual lens product having the default quality test information depending on a situation in which the individual lens product has been used.

The reason why the lens performance changes accompanying use is that backlash and dimensional change of a lens barrel of an interchangeable lens and the like occur due to the repeated driving of each unit and the deterioration of components. The tendency of the performance change can be confirmed by the various quality tests described above. In contrast, the various quality tests described above are set under extremely severe conditions, and are performed independently for each test content, so that they do not necessarily match the situations in which the user actually uses the product.

Accordingly, it is necessary to consider various quality test information in combination in order to predict performance changes that match the situation in which the user uses the product. However, it is extremely difficult to derive a law of performance change based on a plurality of various test conditions and test results, and to create a multidimensional map and the like that indicate the relation between use conditions and performance changes. Accordingly, machine learning using, for example, a neural network by which a plurality of elements can be analyzed in combination is used. As a result for inputting the user's lens use state and quality test information used and performing learning by using the fourth information, which is the lens performance based on the actual lens usage results, as the teacher data, it is possible to estimate lens performance with less difference between the lens performance changes due to actual operation, and the quality test information.

A learned model is generated by the above learning, and, in the estimation server 1000, the first information and the second information about an arbitrary interchangeable lens, for example, the interchangeable lens 700, is input to the learned model. Thus, it is possible to output the third information, which is the estimated lens performance (generation of the third information). When image data obtained by shooting the measurement chart and the like is used as the fourth information, which is the teacher data, the third information to be output can also be image data. In this case, the MTF % table data described above is generated based on the output image data, the weighting and weighted average and are performed, and thereby the lens performance information can be obtained.

The lens performance items output to serve as the third information may be increased or decreased depending on the product model, or various driving characteristics such as the starting voltage, starting frequency, maximum speed, step-out speed, and driving voltage in the first information may be added to the third information to serve as the lens performance.

Next, the lens quality evaluation based on the performance estimation result, which is the output third information, will be described. For example, when the weighted average value (“BBB” calculated by the formula (2)) based on the MTF % data described above is output to serve as the third information, it can be classified, for example, as shown in Table 2 below.

TABLE 2

| | Quality | Determine need for |
|---|---|---|
| BBB | evaluation result | maintenance |
| Weighted average: | A | No maintenance required |
| 82 and more | | |
| Weighted average: 70 and | B | Adjustment and cleaning |
| more and less than 82 | | recommended |
| Weighted average: | C | Overhaul recommended |
| less than 70 | | |

Here, as shown in Table 2, quality evaluation result for the lens quality is classified into A rank, B rank, and C rank. For example, a weighted average value of 82 or more is classified into rank A, a weighted average value of 70 or more and less than 82 is classified into rank B, and a weighted average value of less than 70 is classified into rank C. A notification about a message according to the rank is provided to the user. In rank A, for example, a notification in which no maintenance is required is provided to the user, as shown in Table 2. In rank B, for example, a notification in which adjustment/cleaning is recommended is provided to the user. In rank C, for example, a notification in which overhauling is recommended is provided to the user.

Alternately, instead of classifying the evaluation result into the above ranks, the user may be informed of the detailed deterioration degree of each driving unit, or the user may be informed of the output third information itself. Based on the first information and the like acquired during estimation, the first information assuming the trend of using the lens in the future may be newly generated, the lens performance in the future may be estimated, and notification about the transition and the like may be provided. Additionally, the present inventing is not limited thereto, and the lens quality information about which the user is notified may be the information other than the above information, depending on the situation.

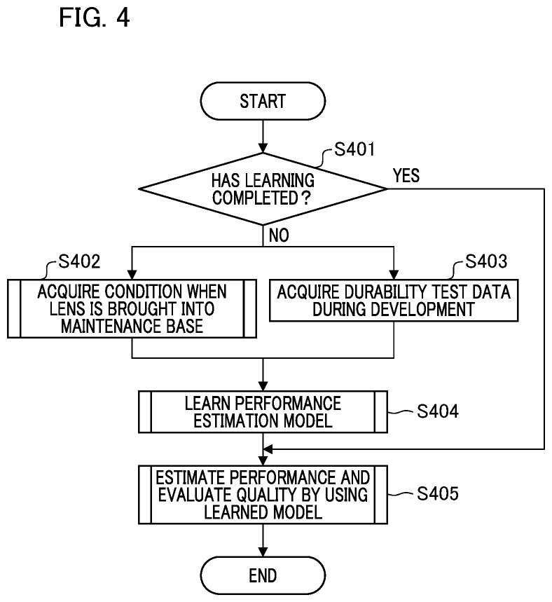

FIG. 4 is a flowchart illustrating a process flow of lens quality evaluation that performs the learning phase and the estimation phase in the first embodiment. With reference to FIG. 4, a flow from the learning phase in which the interchangeable lens 100 is used to the estimation phase in which the quality of the interchangeable lens 700, which is an optional interchangeable lens, is evaluated will be described. Each operation (process) shown in the flowchart of FIG. 4 is controlled by each control unit or each processing unit executing a computer program.

First, in step S401, it is determined whether or not the lens performance estimation function has already been acquired by the machine learning by the processing unit 630, that is, whether or not there are learned data, or whether or not the learning of the learned data is sufficient. As a result of the determination, when there are no learned data or when there are learned data but the learning of the learned data is not sufficient, the process proceeds to step S402, which is the learning phase. As a result of the determination, if there are learned data and the learning of the learned data is sufficient, the process proceeds to step S405, which is the estimation phase. A predetermined threshold may be provided to determine whether or not the learning is sufficient by the predetermined threshold, or whether or not the learning is sufficient may be determined by the number of times the parameter is updated, and the present invention is not limited thereto, and any other method can be used if whether or not the learning is sufficient can be determined.

Next, in step S402, the interchangeable lens 100 is measured, and first information indicating the use state of the interchangeable lens and the fourth information indicating the lens performance after the use of the interchangeable lens are acquired by the measurement apparatus 200 (first acquisition process). In the first embodiment, the measurement apparatus 200 also functions as a first acquisition unit that acquires the first information and the fourth information.

Next, in step S403, second information about the quality test performed in the development process of the interchangeable lens is acquired by the server apparatus 400 (second acquisition process). In the first embodiment, the server apparatus 400 also functions as a second acquisition unit that acquires the second information. Additionally, the order of process in steps S402 and S403 may be reversed.

Next, in step S404, in order to acquire the lens performance estimation function of the interchangeable lens, machine learning using the learning model is performed by the processing unit 630, and the learned model is generated (first processing process). In the first embodiment, the processing unit 630 also functions as a first processing unit that generates a learned model. The learned model is a model in which parameters in the learning model are adjusted by performing machine learning by using a variety of information including the first information, the second information, and the fourth information. The learned model is adjusted by updating parameters in the learned model as required, and thereby a latest learned model can be created. Next, in step S405, the processing unit 1030 generates the third information based on the learned model acquired in step S404, and the processing unit 1030 performs the lens quality evaluation for the interchangeable lens 700, which is an arbitrary interchangeable lens, based on the generated third information.

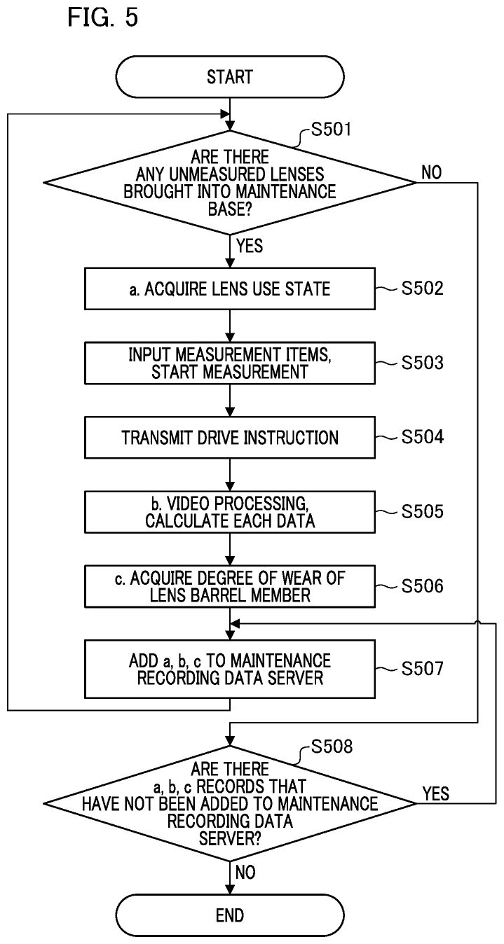

Next, the process for acquiring the lens condition when the interchangeable lens 100 is brought into the maintenance base in step S402 shown in the flowchart of FIG. 4 will be described in detail below with reference to FIG. 5, which is a sub-flow of step S402. FIG. 5 is a flowchart illustrating the measurement processing of the lens condition when the interchangeable lens 100 is brought into the maintenance base in the first embodiment.

First, in step S501, it is determined whether or not an interchangeable lens to which measurement has not been performed has been brought into a specific maintenance base in response to a request from a user for maintenance of the interchangeable lens. When an interchangeable lens on which measurement has not been performed has been brought into the specific maintenance base, the process proceeds to step S502. When an interchangeable on which measurement has not been performed lens has not been brought into the special maintenance base, the process proceeds to step S508. The determination is performed by a control unit provided in an information processing apparatus or the like at the specific maintenance base, based on the information recorded in a memory or the like. Alternatively, each maintenance base may be connected by the network so that the control unit can determine whether or not the lens brought into any maintenance base is an interchangeable lens to which measurement has not been performed. “Bring into” includes a case in which a user sends the interchangeable lens or the user directly brings the interchangeable lens into a specific maintenance base, and a case in which the user sends the interchangeable lens to the maintenance base through a lens manufacturer, a mass retailer where the user purchases the interchangeable lens.

Even in the interchangeable lens on which the process from steps S502 to S507 below has been performed, the interchangeable lens may be treated as an interchangeable lens on which measurement has not been performed if the interchangeable lens has passed a predetermined number of days or years. For example, an interchangeable lens that has been impacted or submerged by a fall or the like, or an interchangeable lens that has been used in extreme environments such as hot sand or an extremely cold place may be treated as an interchangeable lens on which measurement has not been performed. The interchangeable lens is treated as the interchangeable lens 100.

Next, in step S502, an interchangeable lens, for example, the interchangeable lens 100, is mechanically and electrically connected to the measurement apparatus 200. The controller 160 acquires, for example, lens use state information and lens model information, which is the first information stored in the internal memory 140 of the interchangeable lens 100. After acquisition, the controller 160 transmits the first information to the measurement apparatus 200 via the communication unit 150. The transmitted first information is stored in the storage unit 244 of the measurement terminal 240 by the controller 246 via the communication unit 232 and the communication unit 242 of the measurement apparatus 200.

Next, in step S503, the items and conditions of the performance measurement and the measurement start timing are input from the input unit 245 of the measurement terminal 240, and the controller 246 transmits a measurement drive instruction, which serves as a performance measurement instruction to the interchangeable lens 100, to the image pickup apparatus 230. Next, in step S504, the controller 235 transmits the measurement drive instruction to the interchangeable lens 100 via the communication unit 232 based on the measurement drive instruction transmitted to the image pickup apparatus 230 via the communication unit 242.

Next, in step S505, the controller 160 acquires a video signal of the image pickup unit corresponding to the operation of the interchangeable lens 100. After acquisition, the video signal is transmitted to the measurement terminal 240 via the communication unit 232 and the communication unit 242 of the measurement apparatus 200. After transmission, data are input to each table of MTF % data by the controller 246 and stored in the storage unit 244 of the measurement terminal 240. In this case, although not shown in the flow of FIG. 5, each performance data of the interchangeable lens 100 is also sequentially acquired by performing the same process, and the controller 246 stores each of the acquired performance data in the storage unit 244 of the measurement terminal 240 to serve as the fourth information.

Next, in step S506, an operator who maintains the interchangeable lens 100 performs visual observation, various operations, disassembly, and the like and confirms the degree of wear of the various components configuring the interchangeable lens 100. After confirmation, the degree of wear of the various components configuring the interchangeable lens 100 is input from the input unit 245 to the measurement terminal 240, and the controller 246 stores it in the storage unit 244 of the measurement terminal 240 to serve as the fourth information. Additionally, the measurement apparatus 200 may be provided with a sensor to measure the appearance and the degree of wear of the various components configuring the interchangeable lens 100, or to perform measurement in combination with the confirmation operation performed by the operator.

Next, in step S507, the controller 246 transmits the first information and the fourth information acquired in steps S502, S505, and S506, and stored in the storage unit 244 of the measurement terminal 240 to the server apparatus 300 via the communication unit 243. The transmitted first information and the fourth information are stored in the storage unit 320 by the controller 330 via the communication unit 310 of the server apparatus 300. Subsequently, the process returns to step S501.

Next, in step S508, the controller 330 determines whether or not any one of each piece of information (information acquired in steps S502 to S506) described above that has not yet been stored exists in the server apparatus 300. The target for the determination is an interchangeable lens that has been brought into any of the maintenance bases in the past, and for which the operation (processes) corresponding to steps S502 to S506 has already been performed. When information that has not been stored yet exists as a result of the determination, the process returns to step S507, and the information including the first information or the fourth information that has not been stored yet is stored in the storage unit 320 of the server apparatus 300. That is, records of maintenance performed in the past are also stored in the server apparatus 300. When the information described above has been stored as a result of the determination, that is, when all the records to be stored have been stored in the server apparatus 300, the process ends.

The flowchart shown in FIG. 5 is a method for collecting and acquiring the first information and the fourth information in the interchangeable lens 100 actually used by the user.

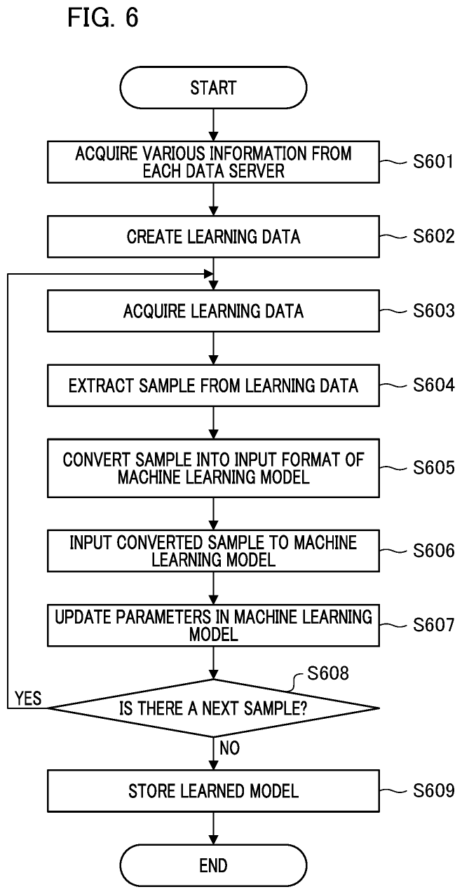

Next, the learning of the performance estimation model in step S404 shown in the flowchart of FIG. 4 will be described in detail below with reference to FIG. 6, which is a sub-flow of step S404. FIG. 6 is a flowchart illustrating the learning processing of the lens performance estimation model in the first embodiment.

First, in step S601, the controller 330 transmits the first information and the fourth information in the interchangeable lens 100 actually used by the user from the server apparatus 300 to the server apparatus 500 via the communication unit 310. After transmission, the information is stored in the storage unit 520 of the server apparatus 500 by the controller 530. Additionally, the controller 440 of the server apparatus 400 transmits the second information in each model of the interchangeable lens to the server apparatus 500 via the communication unit 410. After transmission, the information is stored in the storage unit 520 of the server apparatus 500 by the controller 530.

Next, in step S602, the controller 530 associates the first and fourth information stored in the storage unit 520 of the server apparatus 500 with the second information between the same model of the interchangeable lens. By the association, learning data holding the first information, the second information, and the fourth information are created for each interchangeable lens.

Next, in step S603, the controller 330 transmits the learning data that has been created to the learning server 600 via the communication unit 510. After transmission, the data are stored in the storage unit 620 of the learning server 600 by the processing unit 630. Next, in step S604, the processing unit 630 selects the learning data of an arbitrary interchangeable lens to serve as sample data.

Next, in step S605, the processing unit 630 performs processing for a missing value, normalization, conversion processing including category variable conversion, and the like on the sample data depending on the case, and converts the sample data into a format in which sample data can be input to the machine learning model. The converted sample data are treated as sample data that have been converted. Additionally, the processing order in steps S604 and S605 may be reversed.

Next, in step S606, the processing unit 630 inputs the first and second information in the converted sample data to the learning model (machine learning model) to serve as input data, and inputs the fourth information to the learning model (machine learning model) to serve as the teacher data. Next, in step S607, the processing unit 630 adjusts and updates each parameter in the learning model based on the above variety of data that have been input (first, second, and fourth information). Thus, it is possible to acquire the learned model in which each parameter in the learning model is optimized.

Next, in step S608, the processing unit 630 determines whether or not another sample data (next sample data) exist in the learning data. If it is determined that other sample data exist in the learning data, the process returns to step S603, and the processes from steps S603 to S607 are performed by using the sample data. If it is determined that no other sample data exists in the learning data, the processing unit 630 determines that the learning rate is sufficient, and the process proceeds to step S609. The processing unit 630 may determine whether or not the learning rate of the learning data is sufficient. In this case, when it is determined that no other sample data exists and the learning rate is sufficient, the process proceeds to step S609. When it is determined that no other sample data exists and the learning rate is insufficient, learning is performed until the learning rate is determined to be sufficient. The examples of the learning include iterative learning using the same sample data. When, in performing the determination, the next sample data exist, the process returns to step S603 irrespective of whether or not the learning rate is sufficient, and the processes of steps from S603 to S607 are performed by using the sample data.

Next, in step S609, the processing unit 630 stores the learned model in the storage unit 620 of the learning server 600.

As described above with reference to the flowcharts in FIG. 5 and FIG. 6, steps S401 to S404 in FIG. 4 are the learning phases in the first embodiment. The learned model in which machine learning has been performed in the learning phase has a lens performance estimation function.

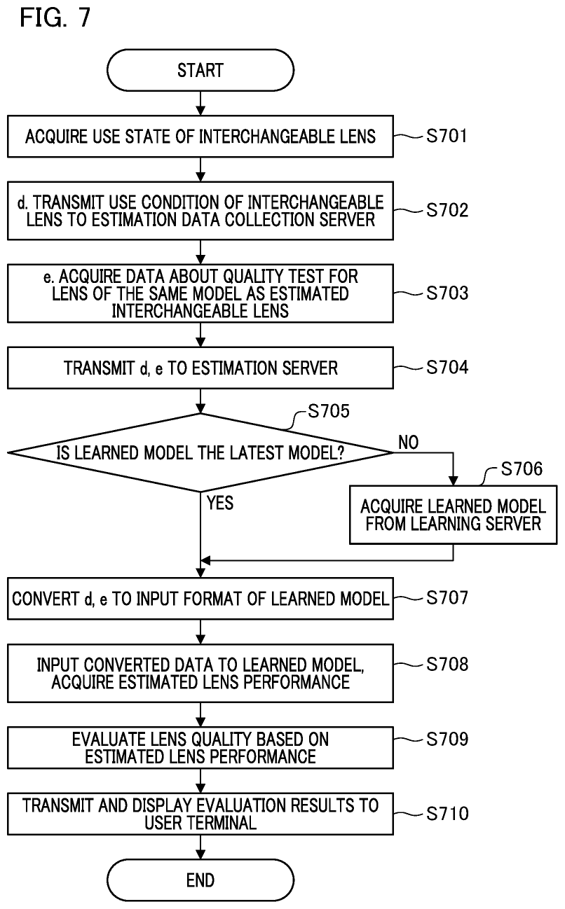

Next, the performance estimation and quality evaluation processing for the interchangeable lens 700 by using the learned model in step S405 shown in the flowchart in FIG. 4 will be described in detail below with reference to FIG. 7, which is a sub-flow of step S405. FIG. 7 is a flowchart illustrating a process flow of the lens performance estimation and quality evaluation in the first embodiment.

First, in step S701, the interchangeable lens 700 to be a target for quality evaluation is connected to the user terminal 800. Subsequently, the controller 760 of the interchangeable lens 700 acquires the first information indicating the use state of the interchangeable lens 700 stored in the internal memory 740, and transmits the first information to the user terminal 800 via the communication unit 750. After transmission, the first information is stored in the storage unit 840 of the user terminal 800 by the controller 860.

Next, in step S702, the controller 860 transmits the first information acquired in step S701 to the server apparatus 900 via the communication unit 850. After transmission, the first information is stored in the storage unit 920 of the server apparatus 900 by the controller 930. Next, in step S703, the controller 440 transmits the second information in the same model as the interchangeable lens 700 stored in the storage unit 430 of the server apparatus 400 to the server apparatus 900 via the communication unit 410. After transmission, the second information is stored in the storage unit 920 of the server apparatus 900 by the controller 930.

Next, in step S704, the controller 930 transmits the first information and the second information stored in the storage unit 920 to the estimation server 1000 via the communication unit 910. After transmission, the first information and the second information are stored in the storage unit 1020 of the estimation server 1000 by the processing unit 1030.

Next, in step S705, the processing unit 1030 confirms and determines whether or not the lens performance estimation function stored in the storage unit 1020 is the latest learned model through the communication unit 1010 in connection with the learning server 600. As a result of the determination, if the lens performance estimation function is the latest learned model, the process proceeds to step S707, and if not, the process proceeds to step S706.

Next, in step S706, the processing unit 1030 acquires the learned model from the storage unit 620 of the learning server 600 via the communication unit 1010. After acquisition of the learned model, the processing unit 1030 stores the learned model in the storage unit 1020 of the estimation server 1000.

Next, in step S707, the processing unit 1030 performs the processing for a missing value, normalization, category variable conversion, and the like on the first information and the second information acquired in step S705, depending on the case, the first information and the second information consequently become data that can be input to the learned model. The converted sample data are treated as sample data that have been converted.

Next, in step S708, the processing unit 1030 inputs the converted data to the learned model, and generates and acquires third information that is the estimated lens performance (second processing process). In the first embodiment, the processing unit 1030 also functions as a second processing unit that generates the third information. The processing unit 1030 estimates various lens performances of the interchangeable lens 700 based on the third information.

Next, in step S709, the processing unit 1030 determines and evaluates the lens quality of the interchangeable lens 700 based on the third information (estimation result of the lens performance) generated in step S708. In the first embodiment, the processing unit 1030 also functions as a determination unit that performs predetermined determination on the interchangeable lens 700 based on the third information and evaluates the lens quality.

Next, in step S710, the processing unit 1030 transmits the lens quality evaluation result of the interchangeable lens 700 to the user terminal 800 via the communication unit 1010. After transmission, the lens quality evaluation result is displayed on the display unit 830 of the user terminal 800 by the controller 860.

Thus, it is possible to evaluate the lens quality of the interchangeable lens 700 that is owned (possessed) or temporarily managed by any user by performing the processes illustrated in the flowchart in FIG. 7.

As described above, the lens performance estimation is possible in which, for example, the difference between the durability information and the lens performance change caused by the actual operation is suppressed by using the quality evaluation method (information processing method) that uses the information processing system according to the first embodiment. Therefore, it is possible to provide an information processing apparatus that can easily evaluate the lens quality with a high accuracy according to the use state of each interchangeable lens unit.

In the first embodiment, a large amount of learning data is required for realizing the lens performance estimation with a high accuracy by machine learning. In the first embodiment, a large amount of learning data can be easily acquired by utilizing the maintenance base when acquiring the learning data as described above. Conventionally, there is a process for confirming the lens performance of various interchangeable lenses brought into the maintenance base before a maintenance operation. Specifically, since a large amount of learning data has already been stored in the maintenance bases all over the world, the learning data can be utilized in the first embodiment.

Additionally, even after the start of the operation of the information processing system (quality evaluation system) in the first embodiment, it is possible to increase the learning data for machine learning without adding a new operation process at the maintenance base. In the process for confirming the lens performance before a maintenance operation, if there is a matter that has not been confirmed in the past or a matter to be newly confirmed, the matter may be newly added to the process for confirming the lens performance.

Additionally, it is necessary to directly measure each of the evaluation items in order to perform quality evaluation with a high accuracy for each individual of the interchangeable lens. The driving characteristics for each driving unit can be measured by a detection system of a control unit and a driving unit that provide instructions about the driving in the lens, and can be performed, for example, even with a commercially available image pickup apparatus. In contrast, for the measurement of the optical characteristics, a measurement chart and dedicated equipment including a driving stage are required. Additionally, the lens needs to be disassembled as needed when the degree of wear of the lens barrel components is confirmed. Therefore, the lens quality evaluation needs to be performed at a place, for example, a maintenance base with an advantageous measurement environment.

According to the quality evaluation method according to the first embodiment, the user can evaluate the lens quality if the user can transmit the record of the internal memory 740 of the interchangeable lens 700 to the estimation server 1000 via the user terminal 800. Specifically, a workload on the user is reduced, and the lens quality evaluation with a high accuracy can be easily performed by applying the information processing system of the first embodiment.

Additionally, it is possible to easily assist the user in determining whether or not maintenance is necessary, estimate the maintenance cost and the process time, evaluate the price of the used lens, and specify the defective part, by applying the quality evaluation system of the first embodiment. In addition, the user can easily evaluate the lens quality by applying the quality evaluation system of the first embodiment. Consequently, many effects can be expected, including the improvement in the reliability of products, the establishment of a stable used market because the reason for the price of used lenses is provided, the stabilization of the value of interchangeable lenses as assets, and the lowering of hurdles for new users to enter.

### Second Embodiment

When there are variations in the initial performance of each individual lens, lens performance of after use in each individual is slightly different even if the use is similar. In the second embodiment, a description will be given of a quality evaluation method if there is a difference in performance for each interchangeable lens from the time of shipment due to a manufacturing error or an assembly error of components in the interchangeable lens.

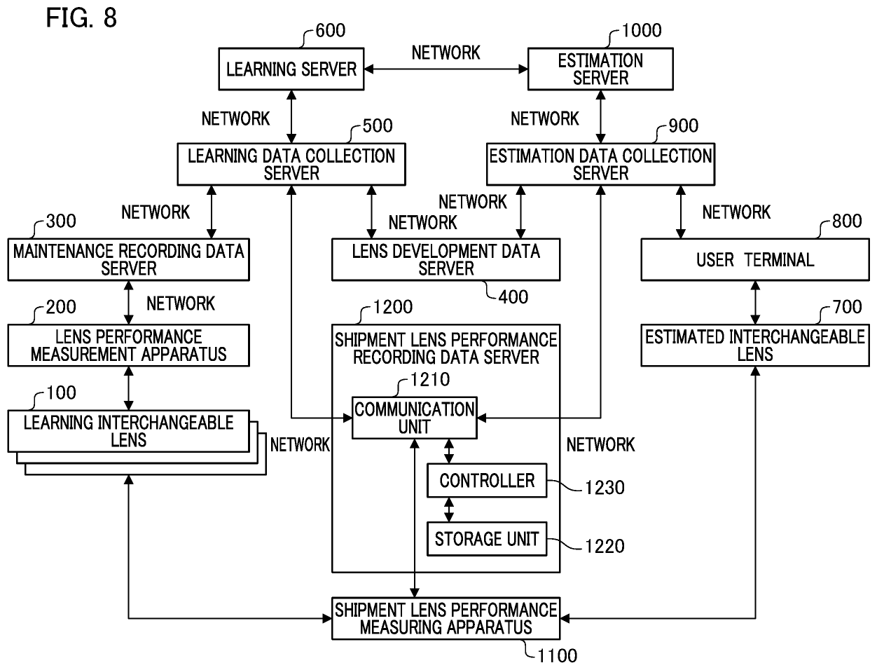

FIG. 8 is an example of a configuration diagram of an information processing system (quality evaluation system) in the second embodiment. The information processing system of the second embodiment is configured to newly add a shipment lens performance measurement apparatus (hereinafter, referred to as a “measurement apparatus”) 1100 and a shipment lens performance recording data server (hereinafter, referred to as a “server apparatus”) 1200 to FIG. 1 illustrated as a system configuration diagram of the first embodiment. Other than the measurement apparatus 1100 and the server apparatus 1200, the configuration is the same as that of the information processing system of the first embodiment, and thus, redundant descriptions will be omitted.

The measurement apparatus 1100 measures the lens performance during shipment. Since the configuration of the measuring apparatus 1100 in the second embodiment is the same as that of the measurement apparatus 200 in the first embodiment, a description thereof will be omitted.

The server apparatus 1200 is a database for storing and managing sixth information, which is lens performance during shipment in the interchangeable lens 100 acquired by the measurement apparatus 1100, for each individual of the interchangeable lens 100. The server apparatus 1200 includes a measurement apparatus 1100, the server apparatus 500, and a communication unit 1210 communicable with the server apparatus 900. The server apparatus 1200 further includes a storage unit 1220 for storing (recording) various data and a controller 1230 for controlling the entire server apparatus 1200.

The server apparatus 1200 may be the same as the server apparatus 500 or the same as the server apparatus 900.

The sixth information indicating the shipment lens performance will be described below. The examples of the sixth information include information similar to the fourth information in the first embodiment.

Further, the sixth information may indicate the driving characteristics of the various actuators for driving the driving unit of the interchangeable lens. The driving characteristics include a starting voltage, a starting frequency, a maximum speed, a step-out speed, a driving voltage, and the like, depending on various actuators.

Various initial characteristics and performance variations for each interchangeable lens during shipment can be confirmed by acquiring the various items above by the measurement apparatus 1100. In the second embodiment, the sixth information is added to the first information, which is the lens quality state, to serve as the initial lens performance.

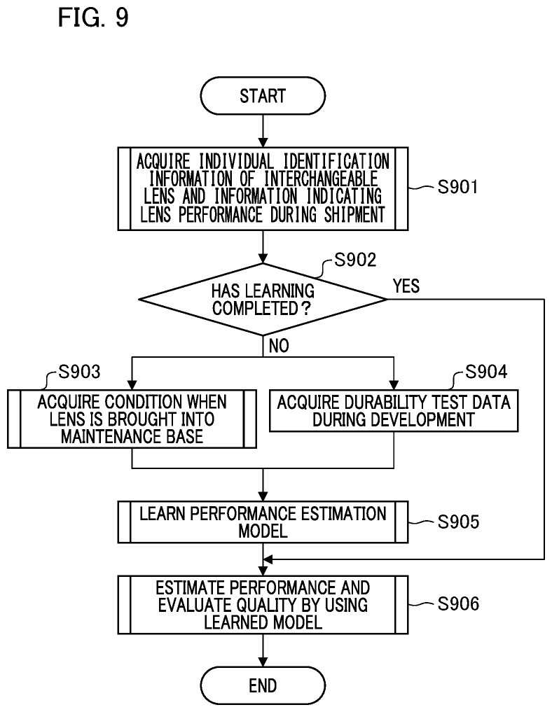

FIG. 9 is a flowchart illustrating a process flow of the lens quality evaluation including the shipment lens performance measurement. A flow from the learning phase to the evaluation of the quality in the estimation phase in the interchangeable lens for which shipment performance has been measured will be described with reference to FIG. 9. Each operation (process) shown in the flowchart in FIG. 9 is controlled by executing a computer program by any one of the respective control units or the respective processing units. Since the processes from steps S902 to S906 in FIG. 9 are the same as those in steps S401 to S405 in FIG. 4, the description thereof will be omitted.

First, in step S901, a predetermined interchangeable lens is measured, and the individual identification information of the interchangeable lens is generated and acquired by the measurement apparatus 1100. Additionally, the sixth information indicating the lens performance of the interchangeable lens 100 (interchangeable lens 700) during shipment is acquired by the measurement apparatus 1100. Subsequently, the processes from steps S902 to S906 are performed.

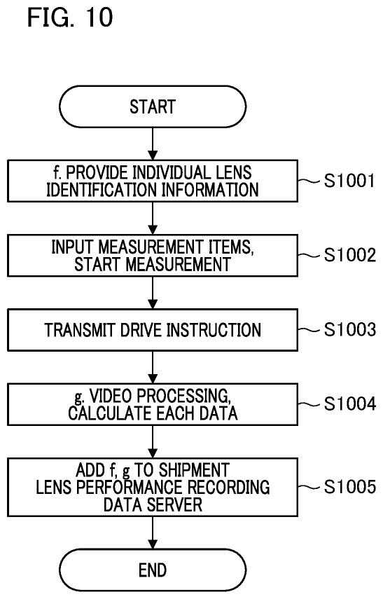

Next, the process of acquiring the performance of the interchangeable lens during shipment in step S901 shown in the flowchart of FIG. 9 will be described in detail below with reference to FIG. 10, which is a sub-flow of step 901. FIG. 10 is a flowchart illustrating the process of the shipment lens performance measurement in the second embodiment.

First, in step S1001, a predetermined interchangeable lens is mechanically and electrically connected to the measurement apparatus 1100. Thus, individual identification information of the interchangeable lens is generated. The individual identification information is stored in the internal memory 140 (internal memory 740) by the controller 160 (controller 760) and stored in the storage unit 244 by the controller 246.

Next, in step S1002, the items and conditions of performance measurement and the measurement start timing are input from the input unit of the measurement terminal 240, and the controller 246 of the measurement terminal 240 transmits a measurement drive instruction, which serves as a performance measurement instruction to the interchangeable lens, to the image pickup apparatus 230. Next, in step S1003, the controller 235 transmits the measurement drive instruction to the interchangeable lens 100 (interchangeable lens 700) via the communication unit 232 based on the measurement drive instruction transmitted from the controller 246 to the image pickup apparatus 230 via the communication unit 242.

Next, in step S1004, the controller 235 acquires a video signal of the image pickup unit corresponding to the operation of the interchangeable lens 100 (interchangeable lens 700). After acquisition, the video signal of the image pickup unit is transmitted to the measurement apparatus 1100. The video signal of the image pickup unit is transmitted to the measurement terminal 240 via the communication unit 232 and the communication unit 242 of the measuring apparatus 1100. After transmission, data are input to each table of MTF % data by the controller 246 and stored in the storage unit 244 of the measurement terminal 240. In this case, although not shown in the flow in FIG. 10, the performance data, the driving characteristic data, and like of the interchangeable lens 100 (interchangeable lens 700) are sequentially acquired by performing the same processing. The acquired performance data, drive characteristic data, and the like are stored in the storage unit 244 of the measurement terminal 240 by the controller 246 to serve as the sixth information.

Next, in step S1005, the controller 246 transmits the individual identification information and the sixth information stored in the storage unit 244 in steps S1001 and S1004 to the server apparatus 1200 via the communication unit 243. The transmitted individual identification information and the sixth information are associated with each other by the controller 1230, and then stored in the storage unit 1220 of the server apparatus 1200. The above process is performed in the interchangeable lens 100 and the interchangeable lens 700.

Thus, the flowchart shown in FIG. 10 is a method for acquiring the sixth information indicating the lens performance during shipment in addition to the individual identification information of the interchangeable lens.

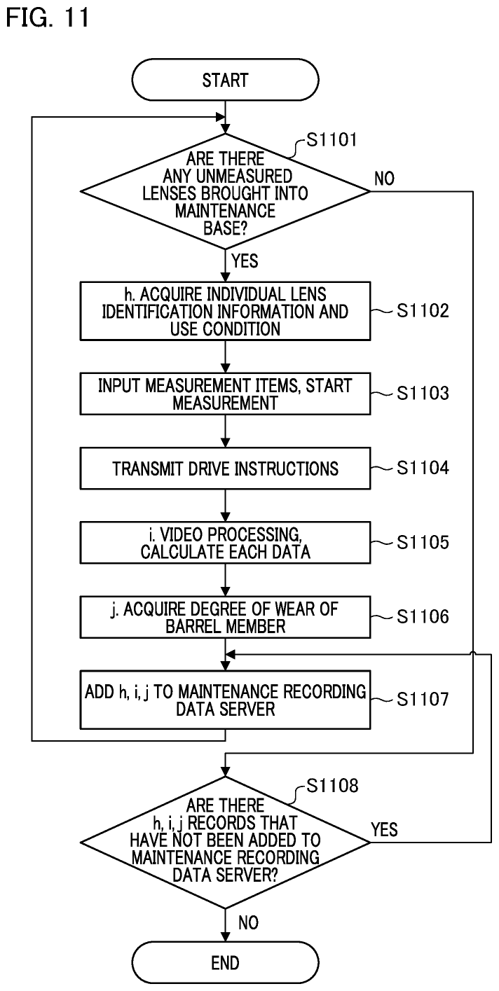

Next, the process for acquiring the lens state when the interchangeable lens 100 is brought into the maintenance base in step S903 shown in the flowchart of FIG. 9 will be described in detail below, with reference to FIG. 11, which is a sub-flow in step S903. FIG. 11 is a flowchart illustrating the measurement processing of the lens state when the lens is brought into the maintenance base in the second embodiment. Steps S1101 and steps S1103 to S1106 in FIG. 11 are respectively the same as those in steps S501 and S503 to S506 in FIG. 5, and thus description thereof will be omitted. Since the process of step S1108 in FIG. 11 is the same as the process of step S508 in FIG. 5, description thereof will be omitted.

First, the process of step S1101 is performed, next, in step S1102, the controller 160 transmits the lens use state information, lens model information, and the like, which are the first information stored in the internal memory 140 of the interchangeable lens 100, to the measurement apparatus 1100. The transmitted first information is stored in the storage unit 244 of the measurement terminal 240 by the controller 246 via the communication unit 150. In step S901, the controller 160 transmits the individual identification information of the interchangeable lens stored in the internal memory 140 of the interchangeable lens 100 to the measurement apparatus 200. The transmitted first information is stored in the storage unit 244 of the measurement terminal 240 by the controller 246 via the communication unit 150.

Next, the processes from steps S1103 to S1106 are performed. Next, in step S1107, the controller 246 associates the individual identification information, the first information, and the fourth information of the interchangeable lens stored in the storage unit 244 with each other, and transmits them to the server apparatus 300 via the communication unit 243. After transmission, the associated information is stored in the storage unit 320 of the server apparatus 300 by the controller 330. Subsequently, the process returns to step S1101. Subsequently, the process of step S1108 is performed.

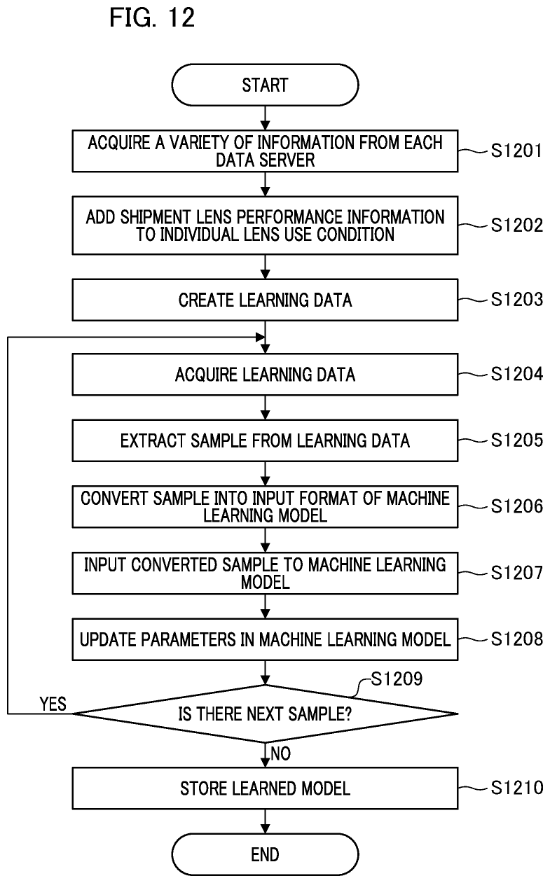

Next, the process of learning the performance estimation model in step S905 shown in the flowchart in FIG. 9 will be described in detail below with reference to FIG. 12, which is a sub-flow of step S905. FIG. 12 is a flowchart illustrating the learning processing of the lens performance estimation model in the second embodiment. Since the processes from steps S1203 to S1210 in FIG. 12 are the same as those from steps S602 to S609 in FIG. 6, description thereof will be omitted.

First, in step S1201, the controller 330 of the server apparatus 300 transmits the individual identification information, the first information, and the fourth information of the interchangeable lens actually used by the user to the server apparatus 500 via the communication unit 310. After transmission, the information is stored in the storage unit 520 of the server apparatus 500 by the controller 530. The controller 1230 of the server apparatus 1200 transmits the individual identification information of each interchangeable lens 100 and the sixth information to the server apparatus 500 via the communication unit 1210. After transmission, the information is stored in the storage unit 520 of the server apparatus 500 by the controller 530. The controller 440 of the server apparatus 400 transmits the second information in each model of the interchangeable lens to the server apparatus 500 via the communication unit 410. After transmission, the information is stored in the storage unit 520 of the server apparatus 500 by the controller 530.

Next, in step S1202, the controller 530 adds the sixth information that indicates the shipment lens performance to the first information indicating the lens quality state stored in the server apparatus 500 based on the individual identification information of the interchangeable lens. Subsequently, the processes from steps S1203 to S1210 are performed.

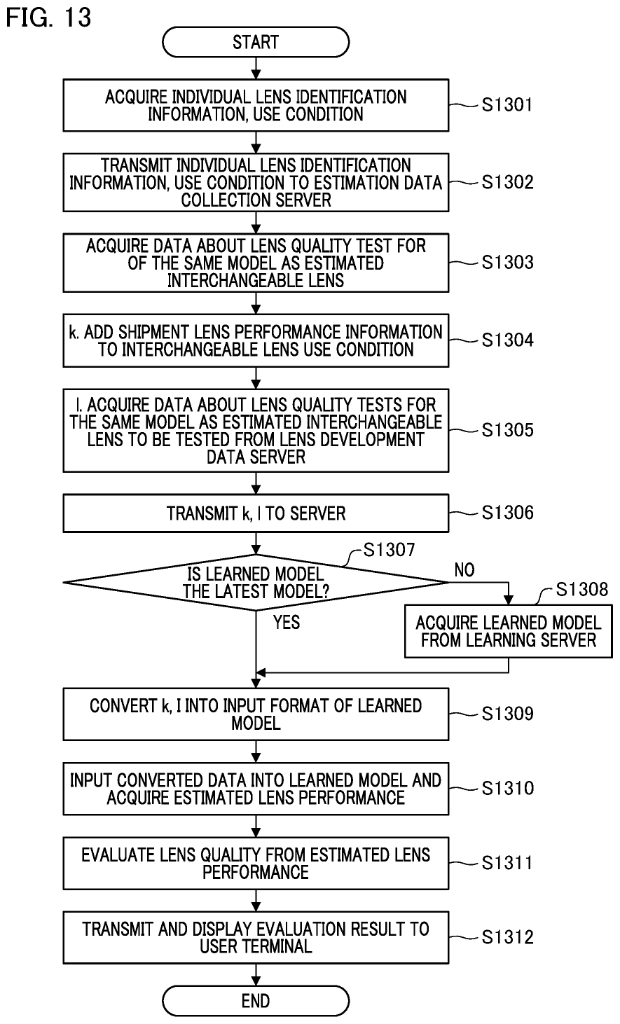

Next, the process of learning of the performance estimation model in step S906 shown in the flowchart in FIG. 9 will be described with reference to FIG. 13, which is a sub-flow of step 906. FIG. 13 is a flowchart illustrating the process of the lens performance estimation and quality evaluation in the second embodiment 2. Since the processes from steps S1305 to S1312 in FIG. 13 are the same as the processes from steps from S703 to S710 in FIG. 7, description thereof will be omitted.

First, in step S1301, the interchangeable lens 700, which is the target for quality evaluation, is connected to the user terminal 800. The controller 760 of the interchangeable lens 700 acquires the individual identification information of the interchangeable lens stored in the internal memory 740 and the first information indicating the use state of the interchangeable lens, and transmits the information to the user terminal 800 via the communication unit 750. After transmission, the transmitted information is stored in the storage unit 840 of the user terminal 800 by the controller 860.

Next, in step S1302, the controller 860 transmits the individual identification information and the first information of the interchangeable lens acquired in step S1301 to the server apparatus 900 via the communication unit 850. After transmission, the transmitted information is stored in the storage unit 920 of the server apparatus 900 by the controller 930.

Next, in step S1303, the controller 930 acquires the sixth information of the individual that is the same as the interchangeable lens 700 stored in the storage unit 1220 of the server apparatus 1200 via the communication unit 910 based on the individual identification information of the interchangeable lens acquired in step S1301. After acquisition, the acquired information is stored in the storage unit 920 of the server apparatus 900 by the controller 930.

Next, in step S1304, the controller 930 adds the sixth information of the individual that is the same as the interchangeable lens 700 to the first information acquired by the user terminal 800 stored in the storage unit 920. Subsequently, the processes from steps S1305 to S1312 are performed.

Thus, the quality evaluation method using the information processing system in the second embodiment is used and the relation between the shipment lens performance, the use state, and lens performance of each lens is acquired by machine learning, and thereby, it is possible to provide an information processing apparatus enabling lens quality evaluation also taking into consideration individual variation during shipment. Additionally, it is possible to perform lens performance estimations that also reflect the influence of individual variation during shipment.

Additionally, when the lens quality is evaluated based on the estimated lens performance in the second embodiment, it is possible to perform evaluation as not only an absolute performance value (absolute value), but also a relative value compared with the performance during shipment. Accordingly, the user can confirm the lens quality in the form of a degree of performance change to the lens use experience in the past. Additionally, it can be said that the above relative evaluation method is effective also for an individual in which individual variation easily appears in the lens quality evaluation, and lens use state is close to the state during shipment.

Additionally, the third information that is an estimated lens performance may be generated based on the learned model generated by the information processing apparatus described in each embodiment, and an inspection apparatus that evaluates the quality of a predetermined interchangeable lens based on the third information may be added to the information processing system of each embodiment. Thus, it is possible to perform the process for evaluating the lens quality of the interchangeable lens described in each embodiment even in an inspection apparatus that cannot generate the learned model. The inspection apparatus includes an acquisition unit (third acquisition unit) that acquires a learned model in a predetermined lens, and acquires first information and second information. The inspection apparatus further includes a processing unit (second processing unit) that generates the third information that is the estimated lens performance of the interchangeable lens based on the first information, the second information, and the learned model acquired by the acquisition unit, and evaluates the quality of the predetermined interchangeable lens based on the third information. The inspection apparatus may be connected to the information processing apparatus described in each of the embodiments by a line or may be an inspection apparatus in which any of the information processing apparatuses described in each of the embodiments is incorporated.

Additionally, a computer program that implements some or all of the control in the above embodiments may be supplied to each of the information processing apparatus, the server apparatus, the inspection apparatus, and the like via a network or various storage media. The program may be read and executed by a computer (or CPU, MPU, or the like) in the information processing apparatus, the server apparatus, the inspection apparatus, and the like. In this case, the program and the storage medium storing the program configure the present invention.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2021-016339, filed Feb. 4, 2021, which is hereby incorporated by reference wherein in its entirety.

What is claimed is:

1. An information processing apparatus comprising:
a first acquisition unit configured to acquire first information in which a use state of a lens unit having at least one optical element after shipment is recorded;
a second acquisition unit configured to acquire second information in which lens performance or standard of the lens unit or a lens unit different from the lens unit is recorded in advance; and
a first processing unit configured to use the first information and the second information as input data of a predetermined learning model and generate a learned model in which parameters in the learning model are adjusted.

2. The information processing apparatus according to claim 1 further comprising a second processing unit configured to generate third information that is an estimated lens performance of a predetermined lens unit based on the first information, the second information, and the learned model.

3. The information processing apparatus according to claim 1, wherein the first information includes at least any one of drive or control information, temperature information, humidity information, position information of the lens unit, and information about an external force applied to the lens unit.

4. The information processing apparatus according to claim 1, wherein the second information includes at least any one of environmental test information, durability test information, load test information, vibration test information, and impact test information of the lens unit or a lens unit different from the lens unit.

5. The information processing apparatus according to claim 4, wherein the second information includes at least any one of optical performance information, operation performance information, dust-proof or drip-proof performance information, evaluation information in an appearance or operation state, and consumption degree information of components of the lens unit after a predetermined test has been further performed on the lens unit or a lens unit other than the lens unit.

6. The information processing apparatus according to claim 1, wherein the learning model uses fourth information that is lens performance in the lens unit as teacher data.

7. The information processing apparatus according to claim 6, wherein the fourth information includes at least any one of optical performance information, operation performance information, dust-proof or drip-proof performance information, and appearance or operation state information of the lens unit.

8. The information processing apparatus according to claim 7, wherein the first information or the fourth information is acquired when a predetermined inspection is performed after shipment.

9. The information processing apparatus according to claim 4, wherein the second information further includes fifth information including at least any one of design-time information, manufacturing-time information, and catalog data of the lens unit or a lens unit different from the lens unit.

10. The information processing apparatus according to claim 1, wherein the first information further includes sixth information including at least any one of optical performance information, operation performance information, dust-proof or drip-proof performance information, and appearance or operation state information of the lens unit.

11. The information processing apparatus according to claim 2, wherein the third information includes at least any one of optical performance information, operation performance information, dust-proof or drip-proof performance information, and appearance or operation state information of the lens unit.

12. The information processing apparatus according to claim 2 further comprising a determination unit configured to perform predetermined determination on the predetermined lens unit based on the third information.

13. An information processing method comprising:
a first acquisition process for acquiring first information in which a use state of a lens unit having at least one optical element after shipment is recorded;
a second acquisition process for acquiring second information in which lens performance or standard of the lens unit or a lens unit different from the lens unit is recorded in advance; and
a first processing process for generating a learned model in which parameters in the learning model are adjusted by using the first information and the second information as input data of a predetermined learning model.

14. The information processing method according to claim 13 further comprising a second processing process for generating third information that is an estimated lens performance of a predetermined lens unit based on the first information, the second information, and the learned model.

15. A non-transitory computer-readable storage medium storing a program for causing a computer to execute an information processing method, the information processing method comprising:
a first acquisition process for acquiring first information in which a use state of a lens unit having at least one optical element after shipment is recorded;
a second acquisition process for acquiring second information in which lens performance or standard of the lens unit or a lens unit different from the lens unit is recorded in advance; and
a first processing process for generating a learned model in which parameters in the learning model are adjusted by using the first information and the second information as input data of a predetermined learning model.

16. An information processing system comprising:
a first acquisition unit configured to acquire first information in which a use state of a lens unit having at least one optical element after shipment is recorded;
a second acquisition unit configured to acquire second information in which lens performance or standard of the lens unit or a lens unit different from the lens unit is recorded in advance; and
a first processing unit configured to use the first information and the second information as input data of a predetermined learning model, and generate a learned model in which parameters in the learning model are adjusted;
a second processing unit configured to generate third information that is an estimated lens performance of a predetermined lens unit based on the first information, the second information, and the learned model; and
a determination unit configured to perform predetermined determination based on the third information.

17. An inspection apparatus comprising:
a third acquisition unit configured to acquire a learned model, first information, and second information about a lens unit, generated by an information processing apparatus;
a second processing unit configured to generate third information that is estimated lens performance of the predetermined lens unit based on the first information, the second information, and the learned model acquired by the third acquisition unit,
the information processing apparatus comprising:
a first acquisition unit configured to acquire the first information in which a use state of the lens unit having at least one optical element after shipment is recorded;
a second acquisition unit configured to acquire the second information in which lens performance or standard of the lens unit or a lens unit different from the lens unit is recorded in advance; and
a first processing unit configured to use the first information and the second information as input data of a predetermined learning model, and generate the learned model in which parameters in the learning model are adjusted.

18. An inspection method comprising:
a third acquisition process for acquiring a learned model, first information, and second information about a lens unit, generated by an information processing apparatus;
a second processing process for generating third information that is an estimated lens performance of the predetermined lens unit based on the first information, the second information, and the learned model acquired by the third acquisition process,
the information processing apparatus comprising:
a first acquisition unit configured to acquire the first information in which a use state of the lens unit having at least one optical element after shipment is recorded;
a second acquisition unit configured to acquire the second information in which lens performance or standard of the lens unit or a lens unit different from the lens unit is recorded in advance; and
a first processing unit configured to use the first information and the second information as input data of a predetermined learning model, and generate the learned model in which parameters in the learning model are adjusted.
